(19) United States
(12) Patent Application Publication
(10) Pub. No.: US 2013/0200040 A1
(43) Pub. Date: Aug. 8, 2013

(54) TITANIUM NITRIDE REMOVAL

(71) Applicant: INTERNATIONAL BUSINESS MACHINES CORPORATION, Armonk, NY (US)

(72) Inventors: John A. Fitzsimmons, Poughkeepsie, NY (US); Shyng-Tsong Chen, Rensselaer, NY (US); Brown C. Peethala, Albany, NY (US); David L. Rath, Stormville, NY (US); Muthumanickam Sankarapandian, Niskayuna, NY (US); Oscar van der Straten, Mohegan Lake, NY (US)

(73) Assignee: INTERNATIONAL BUSINESS MACHINES CORPORATION, Armonk, NY (US)

(21) Appl. No.: 13/828,249

(22) Filed: Mar. 14, 2013

Related U.S. Application Data
(63) Continuation-in-part of application No. 13/343,190, filed on Jan. 4, 2012.

(51) Int. Cl. G03F 7/42; C09K 13/00

(52) U.S. Cl. CPC G03F 7/425; C09K 13/00
USPC 216/17; 252/79.1; 510/176

(57) ABSTRACT

A chemical solution that removes undesired metal hard mask yet remains selective to the device wiring metallurgy and dielectric materials. The present disclosure decreases aspect ratio by selective removal of the metal hard mask before the metallization of the receiving structures without adverse damage to any existing metal or dielectric materials required to define the semiconductor device, e.g. copper metallurgy or device dielectric. Thus, an improved aspect ratio for metal fill without introducing any excessive trapezoidal cross-sectional character to the defined metal receiving structures of the device will result.

### RELATED APPLICATIONS

This application is a continuation-in-part of U.S. patent application Ser. No. 13/343,190 filed on Jan. 4, 2012, the content and disclosure of which are incorporated herein by reference.

### BACKGROUND

The present disclosure relates to removal of metal hard mask materials for microelectronic devices. More particularly, the present disclosure relates to a chemical solution for removing metal hard mask selective to device wiring and dielectric materials.

Interconnect circuitry in semiconductor circuits consists of conductive metallic circuitry surrounded by insulating dielectric material. Silicate glass vapor deposited from tetraethylorthosilicate (TEOS) was widely used as the dielectric material, while alloys of aluminum were used for metallic interconnects.

Demand for higher processing speeds has led to smaller sizing of circuit elements, along with the replacement of TEOS and aluminum alloys by higher performance materials. Aluminum alloys have been replaced by copper or copper alloys due to the higher conductivity of copper. TEOS and fluorinated silicate glass (FSG) have been replaced by the so called low-k dielectrics, including low-polarity materials such as organic polymers, hybrid organic, inorganic materials, organosilicate glass (OSG), and carbon-doped oxide (CDO) glass. The incorporation of porosity, i.e. air-filled pores, in these materials further lowers the dielectric constant of the material.

During dual-damascene processing of integrated circuits, photolithography is used to image a pattern on a device wafer. Photolithography techniques comprise the steps of coating, exposure and development. A wafer is coated with a positive or negative photoresist substance and subsequently covered with a mask that defines patterns to be retained or removed in subsequent processes. Following the proper positioning of the mask, the mask has directed there through a beam of monochromatic radiation, such as ultraviolet (UV) light or deep UV (DUV) light (˜250 nm or 193 nm), to make the exposed photoresist material more or less soluble in a selected rinsing solution. The soluble photoresist material is then removed, or “developed,” thereby leaving behind a pattern identical to the mask.

Thereafter, a wet etch or a gas-phase plasma etch can be used to transfer the patterns of the developed photoresist coating to the underlying layers, which may include hard mask, inter-level dielectric (ILD), and/or etch stop layers. If a gas-phase plasma etch is employed, post-plasma etch residues are typically deposited on back-end-of-the-line (BEOL) structures and if not removed, may interfere with subsequent silicidation, proper metallization or contact formation. Post-plasma etch residues typically include chemical elements present on the substrate and in the plasma gases. For example, if a TiN hard mask is employed, e.g. as a metal hard mask over a dielectric hard mask or as a layer over ILD, the post-plasma etch residues include titanium-containing species, which are difficult to remove using conventional wet cleaning chemistries.

In addition to the need to remove post-plasma residues, it is often desirable to remove or partially etch back the metal hard mask such as a titanium-containing hard mask and/or titanium-containing post plasma etch residue, additional materials that are deposited during the post-plasma etch process such as polymeric residues on the sidewalls of the patterned device and copper-containing residues in the open via structures of the device are also preferably removed. No single wet cleaning composition has successfully removed all of residue and/or hard mask material while simultaneously being compatible with the ILD, other low-k dielectric materials, and metal interconnect materials. Compositions in the art claim to act in such a manner but are extremely less effective than the claims indicate.

The integration of new materials, such as low-k dielectrics, into microelectronic devices places new demands on cleaning performance. At the same time, shrinking device dimensions reduces the tolerance for changes in critical dimensions and damage to device elements. Etching conditions can be modified in order to meet the demands of the new materials. Likewise, post-plasma etch cleaning compositions must be modified. Importantly, the cleaner should not damage the underlying dielectric material or corrode metallic interconnect materials, e.g. sensitive ILD materials such as carbon-doped oxides and metal structures such as copper, tungsten, cobalt, aluminum, ruthenium and silicides thereof, on the device.

Typical trench first metal hard mask integration removes the metal hard mask during the chemical mechanical polish process that removes excess device metallurgy. As integration tolerances tighten, the limited ability to correctly fill the defined metal receiving structures has been clearly demonstrated.

Additional complications arise when a self-aligned via (SAV) process that requires enhanced metal hard mask stability is used to provide additional lithographic process window. While it may be beneficial for metal fill to add trapezoidal cross-sectional character to an integration structure, line to line integration space can suffer if an excessive trapezoidal cross-sectional design is used to enhance metal fill of very high aspect structures. A metal hard mask can be designed such that the lithographic transfer into the metal hard mask will define the desired future trench structure and yet be resistant to undesired damage during reactive ion etch transfer operations into the ILD structures such that a metal fill definition structure may be constructed without significant trapezoidal character. An unfortunate byproduct of this aforementioned process is an increase in aspect ratio, which may further impede proper metallization.

What is needed to advance new technologies is a method to improve the aspect ratio for metal deposition while still maintaining the desired line to line integration spaces. U.S. Pat. No. 7,922,824 suggests the use of quaternary ammonium salts and quaternary ammonium alkali as part of a chemical composition for removing metal hard masks and post-plasma etch residues. However, it teaches away from the use of quaternary ammonium salts and quaternary ammonium alkali without the addition of an acid modifying agent, such as citric acid, and by this teaching as well as the direct omission of quaternary ammonium salts in the list of oxidizing agent stabilizers indicates that quaternary ammonium salts and quaternary ammonium alkali cannot be used alone.

### SUMMARY

A working chemical solution is provided, which removes a metal hard mask material selective to device wiring metallurgy and dielectric materials. Further, a stock chemical solution that can be employed to generate the working chemical solution is provided. The aspect ratio of via holes and cavities can be decreased by removal of the metal hard mask before formation of metal interconnect structures without adverse damage to any existing metal interconnect structures or dielectric materials, e.g. copper or cobalt metallurgy or device dielectric.

According to an aspect of the present disclosure, a chemical composition for removing a metal hard mask and etching residues from a microelectronic device is provided. The chemical composition includes at least one metal protectant at a concentration in a range from 1,000 p.p.m. to 50,000 p.p.m. in weight percentage; an oxidizing agent selected from peroxides and oxidants which do not leave a residue and do not adversely attack copper; a pH stabilizer including at least one quaternary ammonium salt or at least one quaternary ammonium alkali; and an aqueous solution.

According to another aspect of the present disclosure, a chemical composition for a stock solution for generating an etch solution for removal of a metallic material is provided. The chemical composition includes: at least one metal protectant at a concentration in a range from 10,000 p.p.m. to 400,000 p.p.m. in weight percentage; a pH stabilizer including at least one quaternary ammonium salt or at least one quaternary ammonium alkali; and an aqueous solution.

According to yet another aspect of the present disclosure, a method of removing a metal hard mask and etching residues from a microelectronic device is provided. A trench is etched in an interconnect structure by a reactive ion etching process (RIE) through a stack including at least a metal hard mask layer and an inter-layer dielectric. A wet chemical composition for removing the metal hard mask layer selective to the dielectric hard mask layer and the inter-layer dielectric is applied. The chemical composition includes at least one metal protectant at a concentration in a range from 1,000 p.p.m. to 50,000 p.p.m. in weight percentage, an oxidizing agent selected from peroxides and oxidants which do not leave a residue and do not adversely attack copper, a pH stabilizer including at least one quaternary ammonium salt or at least one quaternary ammonium alkali, and an aqueous solution, wherein the composition has a pH in the range of about 7 to about 14.

According to still another aspect of the present disclosure, a method of removing a metal hard mask and etching residues from a microelectronic device is provided. A trench is etched in an interconnect structure by a reactive ion etching process (RIE) through a stack including at least a metal hard mask layer and an inter-layer dielectric. A first wet chemical composition is applied, which includes at least one metal protectant in a first aqueous solution at a concentration in a range from 1,000 p.p.m. to 400,000 p.p.m. in weight percentage. After application of the first wet chemical solution, a second wet chemical composition for removing the metal hard mask layer selective to the inter-layer dielectric is applied. The chemical composition includes at least an oxidizing agent selected from peroxides and oxidants which do not leave a residue and do not adversely attack copper, a pH stabilizer including at least one quaternary ammonium salt or at least one quaternary ammonium alkali, and a second aqueous solution, wherein the composition has a pH in the range of about 7 to about 14.

According to a further aspect of the present disclosure, a method of forming a chemical solution is provided. The method comprising dissolving at least one metal protectant in an aqueous solution including a pH stabilizer at a concentration greater than a solubility limit of the at least one metal protectant in deionized water to form a stock solution.

### BRIEF DESCRIPTION OF THE DRAWINGS

The features and elements of the present disclosure are set forth with respect to the appended claims and illustrated in the drawings.

FIG. 1 illustrates a microelectronic device prior to patterning and etching.

FIG. 2 illustrates the microelectronic device after patterning a lithographic stack layer.

FIG. 3 illustrates the microelectronic device after removal of the lithographic stack and patterning the metal hard mask layer.

FIG. 4A illustrates the microelectronic device after performing a reactive ion etch process selective to a dielectric capping layer, which is herein referred to as a partial RIE, and resulting formation of an etch residue according to an embodiment the present disclosure.

FIG. 4B illustrates the microelectronic device after performing a reactive ion etch process selective to a dielectric capping layer, which is herein referred to as a partial RIE without formation of an etch residue according to an embodiment of the present disclosure.

FIG. 4C illustrates the partially etched microelectronic device after a full wet strip of the metal hard mask layer and the etch residue according to an embodiment of the present disclosure.

FIG. 4D illustrates the partially etched microelectronic device after a partial wet strip of the metal hard mask and the etch residue according to an embodiment of the present disclosure.

FIG. 4E illustrates the partially etched microelectronic device post final reactive ion etch chamfer and clean according to an embodiment of the present disclosure.

FIG. 5A illustrates the microelectronic device after performing a reactive ion etch process selective to an underlying metal interconnect line, which is herein referred to as a full RIE, and resulting formation of an etch residue according to an embodiment of the present disclosure.

FIG. 5B illustrates the microelectronic device after performing a reactive ion etch process selective to an underlying metal interconnect line without formation of an etch residue according to an embodiment of the present disclosure.

FIG. 5C illustrates the fully etched microelectronic device after a full wet strip of the metal hard mask layer and the etch residue according to an embodiment of the present disclosure.

FIG. 5D illustrates the fully etched microelectronic device after a partial wet strip of the metal hard mask layer and the etch residue according to an embodiment of the present disclosure.

FIG. 5E illustrates the fully etched microelectronic device post final reactive ion etch chamfer and clean according to an embodiment of the present disclosure.

### DETAILED DESCRIPTION

The following describes embodiments of the present disclosure with reference to the drawings. The embodiments are illustrations of the disclosure, which can be embodied in various forms. The present disclosure is not limited to the embodiments described below, rather representative for teaching one skilled in the art how to make and use it. Some aspects of the drawings repeat from one drawing to the next. The aspects retain their same numbering from their first appearance throughout each of the preceding drawings.

The present disclosure provides a chemical solution that removes undesired metal hard mask yet remains selective to the device wiring metallurgy and dielectric materials. The present disclosure provides a method for decreasing an aspect ratio by selective removal of the metal hard mask before the metallization of the receiving structures without adverse damage to any existing metal or dielectric materials required to define the semiconductor device, e.g. copper metallurgy or device dielectric. Thus, an improved aspect ratio for metal fill without introducing any excessive trapezoidal cross-sectional character to the defined metal receiving structures of the device will result.

Compositions of the chemical solution may be embodied in a wide variety of specific formulations, as hereinafter more fully described. In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.0001 weight percent, based on the total weight of the composition in which such components are employed.

The compositions of the disclosure may be formulated to substantially remove the titanium-containing residue, the polymeric sidewall reside and/or the copper-containing residue from the surface of the microelectronic device without substantially damaging the underlying inter level dielectric, metal interconnect materials and any dielectric hard mask, if present. The composition may be formulated to remove the metal hard mask layer from the surface of the microelectronic device without substantially damaging the underlying low-k dielectric and metal interconnect materials.

The chemical composition of a working solution of the present disclosure includes an oxidizing agent, a metal protectant, and a pH stabilizer in an aqueous solution. De-ionized water is the principle solvent in the aqueous solution. The solvent can be at least free of any detrimental ions or other materials that could interfere with the cleaning action of the chemical composition or degrade the cleanliness or future performance of the semiconductor circuit. Optionally, a sequestering agent can be added to the solution so as to reduce deleterious effects of unwanted ions by binding with such unwanted ions and reducing the deleterious activity. While de-ionized water is the most preferred solvent for the chemical composition, it is understood that other solvent systems with similar salvation properties to de-ionized water may also act as a possible solvent for the present disclosure. Thus, an aqueous solution is most preferred. However, it is understood that other solvent systems similar to water may also act suitably for the present disclosure. For example, a 25% isopropanol, 75% de-ionized water solvent mixture can be substituted for deionized water to produce satisfactory results.

It has been known that metal protectants can be employed as an additive at a concentration less than 100 parts per million (p.p.m.) to an aqueous solution to retard corrosion of copper. For example, benzotriazole added to an aqueous solution at a concentration less than 100 parts per million in weight percentage can retard corrosion of copper and its alloys by preventing undesirable surface reactions. It has been suggested that a passive layer, consisting of a complex between copper and benzotriazole, is formed when copper is immersed in a solution containing benzotriazole as an additive. The passive layer is insoluble in aqueous and many organic solutions. The effectiveness of benzotriazole has been assumed to saturate at a concentration of about 100 p.p.m. Typically, it has been observed that doubling, or even tripling, the concentration of benzotriazole from 100 p.p.m. concentration does not provide any observable enhancement to the protective effects of benzotriazole as known in the art. Hence, this previous assumption appeared to be a logical conclusion.

Furthermore, an increase in the concentration of benzotriazole in a typical aqueous solution is often disadvantageous in terms of viscosity and residue formation. Specifically, increase in the amount of benzotriazole significantly above the level of 100 p.p.m. has a potential negative effect of increasing the amount of residue formed on organic surfaces such as surfaces of organosilicate glass (OSG) employed in metal semiconductor structures and as the concentration of benzotriazole greatly exceeds the typical 100 p.p.m. use range an increase in viscosity may also occur with respect to that of the typical aqueous solution. Each of these effects due to increasing the concentration of the benzotriazole beyond that of typical usage when viewed in conjunction with the assumed performance saturation as discussed previously, contributed to limited exploration of benzotriazole outside of the typical range of usage for passivation.

The metal protectant is added to the chemical composition. The preferred metal protectants for the present disclosure are hetero-organic inhibitors such as azoles or thiols. Preferably, at least one of benzotriazole (BTA), 1,2,3 triazole, 1,3,4 triazole, 1,2,4 triazole, methyl-thiol-triazole, thiol-triazole, triazole acid, and imidazole are used in the chemical composition. The use of hetero-organic inhibitors as opposed to simple organic compounds is based on the possibility of degradation of organic compounds over time and at extended exposure to certain temperatures. Azoles are organic compounds containing nitrogen atoms with free electron pairs that are potential sites for bonding with copper and that enable inhibiting action. Thiols are organic compounds containing sulfurs atoms with free electron pairs that are potential sites for bonding with copper and that enable inhibiting action. In general, Azole compounds are preferred over thiol compound, as incomplete removal of thiol residues may lead to sulfur atom contamination, a known detriment to copper structures. Thus, when thiol compounds are used, avoidance of Sulfur atom residue is very important. Also, there is a possibility of introduction of other heteroatoms beyond the aforementioned N and S such as Se, P, As etc and/or combinations of heteroatoms either in ring incorporation or as side groups in molecules of these compounds so there is a wide range of derivatives that exhibit good inhibition characteristics. Often when additional heteroatoms are used other attributes introduced with the heteroatom must also be considered. For example, it is understood that thiols produce active protection on copper surfaces; however, thiol use introduces additional considerations of potential negative interactions with copper structures which may require additional post processing such as extended rinse times, specialized or extended post application plasmas, and/or extended vacuum degas processing . . . .

According to an embodiment of the present disclosure, the amount of the metal protectant in the working solution of the present disclosure is set at a level that is at least 10 times the level employed in conventional aqueous solution including the metal protectant, i.e., at a weight percentage greater than 1,000 p.p.m. In one embodiment, the amount of the metal protectant in the working solution can be in a range from 1,000 p.p.m. to 50,000 p.p.m. In another embodiment, the amount of the metal protectant in the working solution can be not less than 2,000 p.p.m. In yet another embodiment, the amount of the metal protectant in the working solution can be not less than 4,000 p.p.m. In still another embodiment, the amount of the metal protectant in the working solution can be not less than 6,000 p.p.m. In a further embodiment, the amount of the metal protectant in the working solution can be not less than 8,000 p.p.m. In one embodiment, the amount of the metal protectant in the working solution can be not more than 30,000 p.p.m. In yet another embodiment, the amount of the metal protectant in the working solution can be not more than 20,000 p.p.m. In still another embodiment, the amount of the metal protectant in the working solution can be not more than 10,000 p.p.m. In a further embodiment, the amount of the metal protectant in the working solution can be not more than 8,000 p.p.m.

The pH stabilizer adjusts the pH level in the chemical composition to a range of about 7 to about 14. In one embodiment, the amount of the pH stabilizer can be selected such that the pH level of the working solution is adjusted to a range of about 7 to about 9. In another embodiment, the amount of the pH stabilizer can be selected such that the pH level of the working solution is adjusted to a range of about 7 to about 8. In one embodiment, the weight percentage of the pH stabilizer in the working solution can be from 0.14% to 14%. In another embodiment, the weight percentage of the pH stabilizer in the working solution can be not less than 0.28%. In yet another embodiment, the weight percentage of the pH stabilizer in the working solution can be not less than 0.7%. In still another embodiment, the weight percentage of the pH stabilizer in the working solution can be not less than 1.4%. In one embodiment, the weight percentage of the pH stabilizer in the working solution can be not greater than 7%. In one embodiment, the weight percentage of the pH stabilizer in the working solution can be not greater than 2.8%. In one embodiment, the weight percentage of the pH stabilizer in the working solution can be not greater than 1.4%. Quaternary ammonium salts (and especially quaternary ammonium basic salts or quaternary ammonium salts including at least one quaternary ammonium basic salt) and quaternary ammonium alkalis are preferred for use as a pH stabilizer in the present disclosure. A quaternary ammonium compound is a positively charged ion based on 4 R groups associated with a nitrogen atom having a descriptive structure as illustrated below

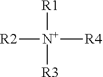

Each of R1, R2, R3, and R4 groups may independently be alkyl or aryl in nature. Each of R1, R2, R3, and R4 group may be identical or different among one another. Thus, a quaternary ammonium compound may be symmetrical or asymmetrical. That is, if an even number of R groups (i.e., R1, R2, R3, and R4 groups) are identical, the quaternary ammonium compound is referred to as symmetrical; and if the number of R groups is odd, the quaternary ammonium compound is referred to as asymmetrical. A quaternary ammonium salt is a compound where a quaternary ammonium ion is associated with a corresponding negatively charged ion to produce a net neutral charge for the overall compound. A quaternary ammonium alkali is a quaternary ammonium salt where the corresponding negatively charged ion is a basic ion, which is commonly a hydroxide ion.

Tetramethylammonium hydroxide (TMAH) is the quaternary ammonium compound that is primarily used in the industry. TMAH is a symmetrical quaternary ammonium compound where all the R groups are identical and consist of methyl groups. However, TMAH is toxic, and causes severe and typically unexpected health problems from exposure. Unlike typical strong bases where an unprotected acute exposure generally results in a caustic burn, TMAH may also introduce a complication of decreased respiratory function. Thus, a quaternary ammonium that does not cause unexpected health side effects is preferable. In the course of the research leading to the present disclosure, it has been determined that tetraethylammonium (TEA) ion does not cause the unexpected health side effects of the tetramethylammonium ion. Thus, tetraethylammonium hydroxide (TEAH) is the most preferred pH stabilizer in the present disclosure. In addition to the ability to adjust pH without the introduction of extraneous undesirable metal ions, such as alkaline earth or alkali metal ions, the TEA ion may also act as a passayating adsorbent on a copper surface at the pH value of the present chemical composition as it is also designed.

The preferred use of TEAH does not preclude the use of other suitable quaternary ammonium hydroxides for use in our solutions. It is believed that any quaternary ammonium hydroxide that may be used to adjust pH in a desired range to be suitable for the purpose of the present disclosure. It is believed that any symmetrical or asymmetrical quaternary ammonium hydroxide that does not introduce a complication of decreased respiratory function is a preferred quaternary ammonium hydroxide. Additionally, if a quaternary ammonium salt can provide some passivation action, such a quaternary ammonium salt is even more preferred. In an illustrative example, one or more of trimethyl-phenyl-ammonium hydroxide, dimethyl-dipropyl-ammonium hydroxide and tetrapropyl ammonium hydroxide can be employed as a pH adjustment agent for the formulation of the present disclosure.

Regardless of whether the passayation action by TEA ions occur, the ability to adjust pH without the introduction of extraneous undesirable metal ions and the decreased hazard of TEAH makes TEAH the most preferred pH stabilizer in one embodiment of the present disclosure. It is understood that other quaternary ammonium salts may also act as pH stabilizing agents with or without the additional passayation action towards a copper surface and as long as the resultant solution does not have a detrimental activity towards a copper surface which can not be mitigated; such a resultant solution is within the purview of the present disclosure.

The oxidizing agent is preferably a peroxide, for example hydrogen peroxide and organic peroxides such as benzoyl peroxide. However, oxidizing agents may also include a non-metal with the ability to oxidize titanium nitride (TiN) to a soluble compound without leaving a metallic residue and oxidants that do not leave a residue or adversely attack copper (Cu). It is very important that the oxidant/oxidizing agent, when dissolved in the chemical process, does not adversely attack copper (Cu). For example, an oxidant may have an activity against copper when used without the modifying agents in the present chemical composition. However, when so mixed with the other agents of the present chemical composition, the activity of the oxidant is modified such that copper is not detrimentally attacked. More specifically, the pH may be adjusted such that copper oxidation is minimized, and/or a surface adsorption action may occur due to agents in the present disclosure such that the copper is protected from oxidation. The tetraethylammonium (TEA) ion, the substantially increased BTA concentration, and the BTA-TEA adduct may act as a passayating adsorbent on a copper surface at the pH value of the present chemical composition as it is so designed.

The approximate bath life of the chemical composition is in the range of about 18 hrs to about 22 hrs. When the chemical activity (using a metric such as the observed TiN etch rate) of the bath drops below 10-15% of the fresh bath, the bath is no longer useful. It is understood that typical methods used to extend solution bath life such as replenishment of the consumed oxidizer in a recirculated solution may be used to extend usable bath life. Additionally, it is known that trace contamination such as minute amounts of some metal ions may also dramatically decrease bath life. As such, the chemical composition of the present disclosure may be of single use (i.e., dispensed on the wafer for cleaning and sent to drain) or multiple uses (i.e., reclaimed after initial processing use and stored for additional use). It is recognized that reclamation may decrease the usable life of a reclaimed chemical bath. The use of a sequestering agent (oxidant stabilizer) in the chemical bath can increase the life of the bath during reclamation process use. In addition, a sequestering agent may be added to an un-reclaimed chemical composition; this sequestering agent may extend the usable bath life of such a composition beyond that of a solution without the sequestering agent either in the reuse condition or in the single use condition. Through the use of a sequestering agent, the oxidizer concentration may be controlled such that excessive oxidant concentration addition to the chemical composition of the present disclosure is not necessary to compensate for oxidant consumption by undesired decomposition due to contamination, rather than by the normal consumption that occurs during the desired cleaning action of the present chemical composition. Thereby, the sequestering agent optimizes the concentration to further minimize the chemical composition's attack on the metallic device layer by enabling a minimization of required oxidizer concentration in the present chemical composition.

Sequestering agents that can be used in the present disclosure are amines and amino acids. The preferred sequestering agents are 1,2-cyclohexanediamine-N,N,N′,N′-tetraacetic acid (CDTA), ethyenediaminetetraacetic acid (EDTA) and diethylenetriaminopentaacetic acid (DTPA). The preferential use of complex sequestering agents, such as CDTA, versus a simple sequestering agent, such as EDTA, is based on the possibility of degradation of a simple sequestering agent over time and at extended exposure to certain temperatures. However, it is understood that for some methods of application a simple sequestering agent such as EDTA may be suitable. For example, a single use system where heating occurs just before the solution dispenses on a wafer for chemical cleaning.

According to an embodiment of the present disclosure, formulations for the chemical composition of the working solution can include:
1. 1,000 p.p.m.-50,000 p.p.m. in weight percentage of at least one metal protectant;
2. 0.1%-20% in weight percentage of an oxidizing agent;
3. 0.14%-14% in weight percentage of a pH stabilizer; and
4. the balance of deionized water or a water-based polar solvent in which water is a predominant portion (more than ½) of the solvent.

An exemplary formulation for the chemical composition of the working solution can be:
1. 10,000 p.p.m. in weight percentage of at least one metal protectant;
2. 9% in weight percentage of an oxidizing agent;
3. 1.4% in weight percentage of a pH stabilizer; and
4. the balance of deionized water or a water-based polar solvent in which water is a predominant portion (more than ½) of the solvent.

According to another embodiment of the present disclosure, formulations for the chemical composition of the working solution can include:
1. 1,000 p.p.m.-50,000 p.p.m. in weight percentage of at least one metal protectant;
2. 0.1%-20% in weight percentage of an oxidizing agent;
3. 0.14%-1.4% in weight percentage of a pH stabilizer;
4. 1 p.p.m.-100 p.p.m. of a sequestering agent; and
5. the balance of deionized water or a water-based polar solvent in which water is a predominant portion (more than ½) of the solvent.

An exemplary formulation for the chemical composition of the working solution can include:
1. 10,000 p.p.m. in weight percentage of at least one metal protectant;
2. 9% in weight percentage of an oxidizing agent;
3. 1.4% in weight percentage of a pH stabilizer;
4. 10 p.p.m. of a sequestering agent; and
5. the balance of deionized water or a water-based polar solvent in which water is a predominant portion (more than ½) of the solvent.

The preferred formulation of the chemical composition is hydrogen peroxide and TEAH in an aqueous solution, wherein the composition has a pH in the range of about 7 to about 9. The chemical composition of the working solution is designed to remove at least some titanium nitride (TiN). However, the chemical composition is also intended to remove at least some etching residues. Accordingly, it is intended to be a full clean. It is understood that in some cases a full clean by a single solution may be too aggressive and a sequential clean using multiple chemical systems may be less aggressive with respect to copper or sensitive ILD structures. Performing a full clean with a single solution is not to be done at the expense of the metallic device layer or sensitive ILD structures. In one embodiment, the composition comprises hydrogen peroxide (H₂O₂), benzotriazole, tetraethylammonium hydroxide, and de-ionized water, and the composition has a pH in the range of about 7 to about 9.

The presence of the metal protectant in amounts greater than 1,000 p.p.m. has the effect of eliminating or minimizing attack on copper, copper-containing alloys, and cobalt-based metallic materials. The concentrations of the metal protectant at 1,000 p.p.m. or greater is far outside the accepted normal use concentrations of copper protectants used in the art, which is 100 p.p.m. or less.

In one embodiment, a working solution can include a high BTA salt concentration achieved through in-situ reaction of BTA with TEAH. In one embodiment, the working solution can be derived from a stock solution by diluting the stock solution with deionized water and adding an additional oxidizing agent. The stock solution can be obtained by dissolving BTA into a solution of TEAH in water.

A stock solution can be formed by dissolving a metal protectant to an aqueous solution including a pH stabilizer. The use of the aqueous solution including the pH stabilizer can allow the metal protectant to be dissolved in quantities that exceed the solubility limit of the metal protectant in deionized water. For example, while the typical working maximum solubility of BTA in water is 6,000 p.p.m., a solution including more than 6,000 p.p.m. of BTA can be obtained if BTA is dissolved in an aqueous solution including a pH stabilizer such as TEAH and water.

According to an embodiment of the present disclosure, formulations for the chemical composition of the stock solution can include:
1. 10,000 p.p.m.-400,000 p.p.m. in weight percentage of at least one metal protectant;
2. 5%-35% (preferably 5%-35% in weight percentage) of a pH stabilizer; and
3. the balance of deionized water or a water-based polar solvent in which water is a predominant portion (more than ½) of the solvent.

An exemplary formulation for the chemical composition of the stock solution can be:
1. 250,000 p.p.m. in weight percentage of at least one metal protectant;
2. 28% in weight percentage of a pH stabilizer; and
3. the balance of deionized water or a water-based polar solvent in which water is a predominant portion (more than ½) of the solvent.

According to another embodiment of the present disclosure, formulations for the chemical composition of the stock solution can include:
1. 10,000 p.p.m.-400,000 p.p.m. in weight percentage of at least one metal protectant;
2. 2%-35% (preferably 5%-35%) in weight percentage of a pH stabilizer;
3. 20 p.p.m.-5,000 p.p.m. of a sequestering agent; and
4. the balance of deionized water or a water-based polar solvent in which water is a predominant portion (more than ½) of the solvent.

An exemplary formulation for the chemical composition of the stock solution can include:
1. 250,000 p.p.m. in weight percentage of at least one metal protectant;
2. 28% in weight percentage of a pH stabilizer;
3. 250 p.p.m. of a sequestering agent; and
4. the balance of deionized water or a water-based polar solvent in which water is a predominant portion (more than ½) of the solvent.

In an illustrative example, 250 grams of BTA can be dissolved into 0.4 liter of a solution including 35% in weight of TEAH and balance deionized water (“35% TEAH solution” hereafter). Vigorous stirring may be employed to dissolve 250 grams of BTA into the 35% TEAH solution to generate an undiluted BTA and TEAH-containing solution (“undiluted solution” hereafter). This results in a solution volume expansion to about 0.8 liters. Addition deionized water (about 0.2 liters) is added to bring the total volume of the diluted solution to 1.0 liter, which is the stock solution. The stock solution includes 25% weight percentage of BTA, i.e., 250,000 p.p.m. of BTA.

A sequestering agent (chelation agent) such as CDTA can be optionally added as a component of the final solution.

A working solution is derived from the stock solution by diluting the stock solution with water and by adding an oxidizing agent such that the final concentration of the working solution is in a range described above.

In one embodiment, a method forming a chemical solution is provided. The method includes dissolving at least one metal protectant to an initial aqueous solution including a pH stabilizer at a concentration greater than a solubility limit of the at least one metal protectant in deionized water to form a stock solution. In one embodiment, the at least one metal protectant can be present at a concentration in a range from 10,000 p.p.m. to 400,000 p.p.m. in weight percentage, and the pH stabilizer can be selected from quaternary ammonium salts and quaternary ammonium alkali. The stock solution can be diluted with water and an oxidant. An etchant for removing a metallic material is formed.

In an illustrative example, a stock solution including 25% of BTA and 28% of TEAH can be employed to generate a working solution including 10,000 p.p.m. of BTA and 9% of hydrogen peroxide. For this purpose, a selected volume of the stock solution can be diluted with water and a 30% hydrogen peroxide solution to provide an aqueous solution including 10,000 p.p.m. of BTA and 9% of hydrogen peroxide, which has a pH of about 8.2. The working solution can be employed for removal of hard mask materials such as TiN.

It is noted that the range of usage of the metal protectant (e.g., BTA) is in a range outside of the accepted practice of use (i.e., not more than 100 p.p.m.). In one embodiment, the stock solution may be formed by adding a metal protectant into an aqueous solution including a combination of water (or a polar solution in which water is the predominant solvent) and a pH stabilizer in a significant quantity (at least 2% in weight percentage) in preference to attempting to dissolve the metal protectant directly in water (or in a polar solution in which water is the predominant solvent and not including the pH stabilizer in a significant quantity). Thus, the stock solution construction is designed to neutralize and improve solubility of the metal protectant through the use of the pH stabilizer. Without wishing to be bound by any particular theory, it is possible that the metal protectant combines with the pH stabilizer to form an adduct (such as a BTA-TEA adduct in the case of BTA and TEAH).

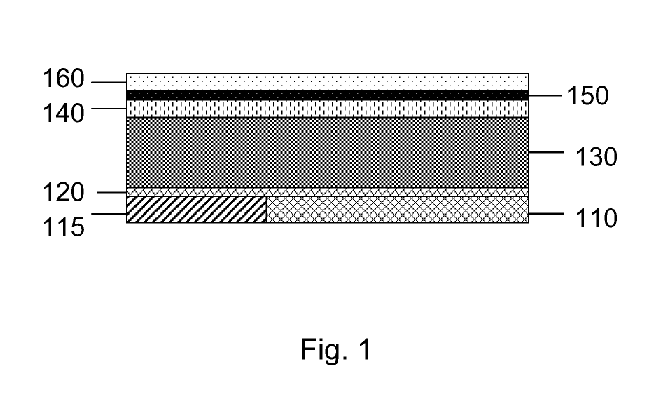

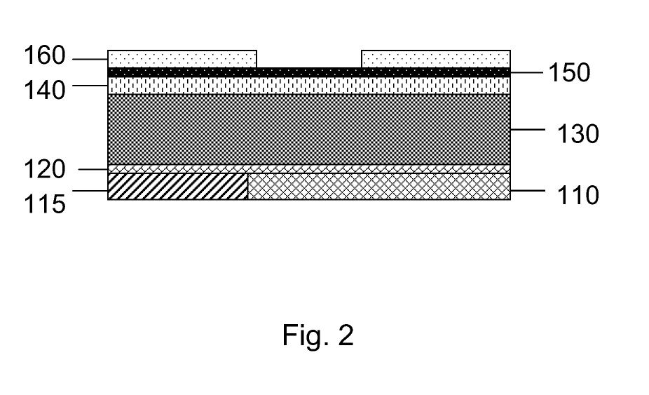

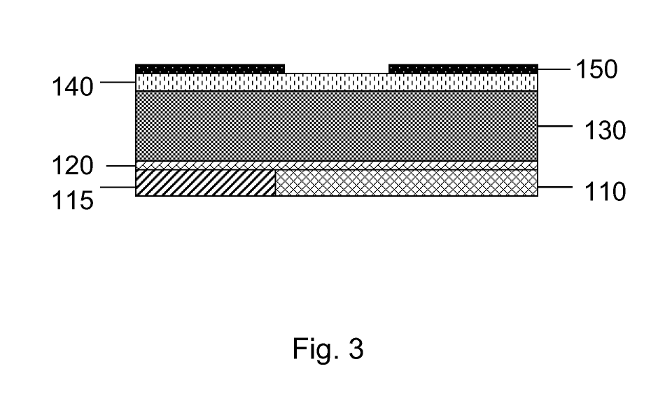

The working solution including any of the chemical compositions described above can be applied to a microelectronic device in multiple ways. Referring now to FIG. 1, the microelectronic device may include protective layers including a lithographic stack layer 160, a metal hard mask layer 150, such as titanium nitride, a dielectric hard mask layer 140, such as tetraethyl orthosilicate (TEOS), an inter-level dielectric (ILD) 130, and a dielectric capping layer 120, such as NBlock, above a metallic device layer (which can be a line structure including copper, a copper alloy such as CuMn or CuAl, cobalt, a cobalt alloy such as CoWP, or combinations thereof) 110 and another inter-level dielectric 115. Prior to application of the chemical composition, the lithographic stack layer 160 is imaged, as shown in FIG. 2, creating an opening in the lithographic stack layer 160 exposing a portion of the metal hard mask layer 150. In FIG. 3, the lithographic stack layer 160 is removed during etch of metal hard mask layer 150. The metal hard mask layer 150 is etched in such a way as to create an opening thus exposing a portion of the dielectric hard mask layer 140. Another etch is performed for forming a trench in the microelectronic device. The etching processes are most likely a reactive ion etching. The etching process often leaves a residue on the microelectronic device and the protective layers, as well as leaving a portion of the protection layers intact.

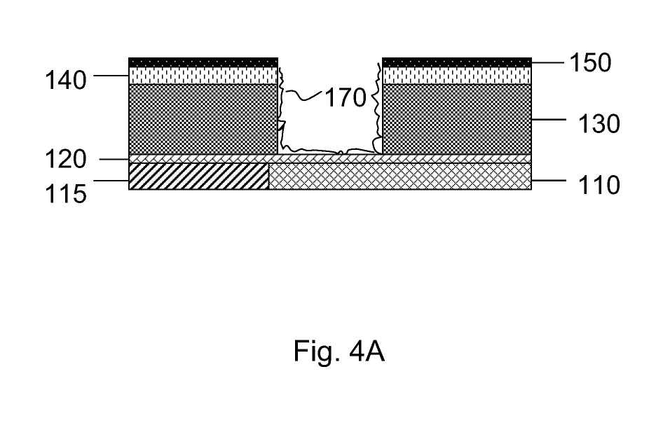

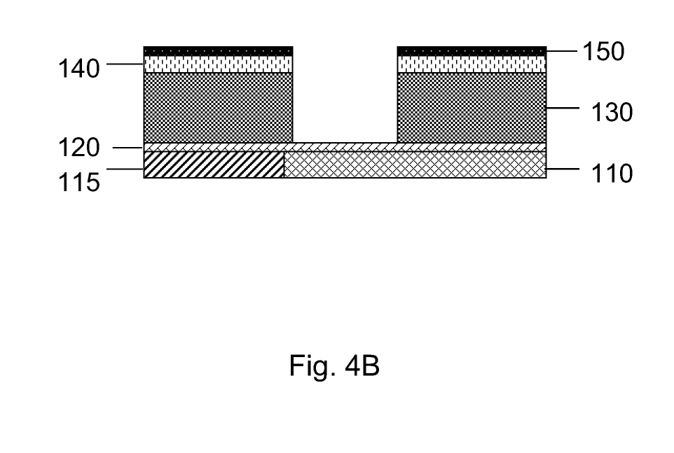

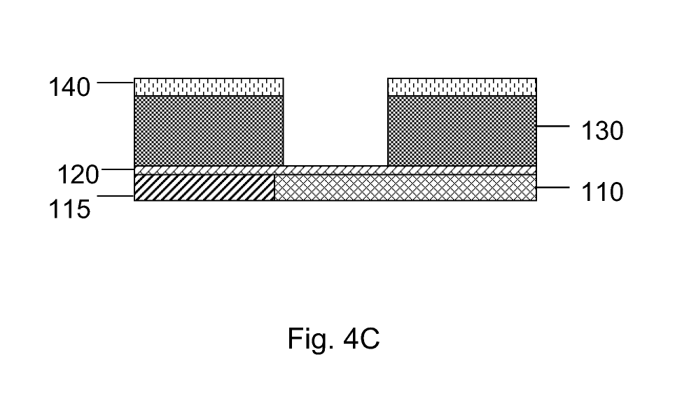

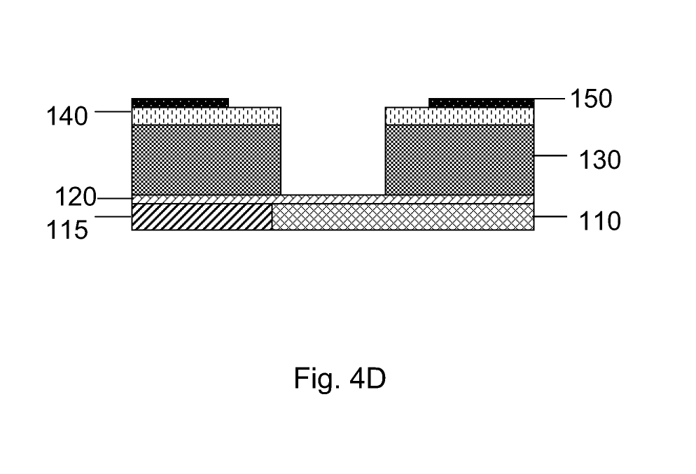

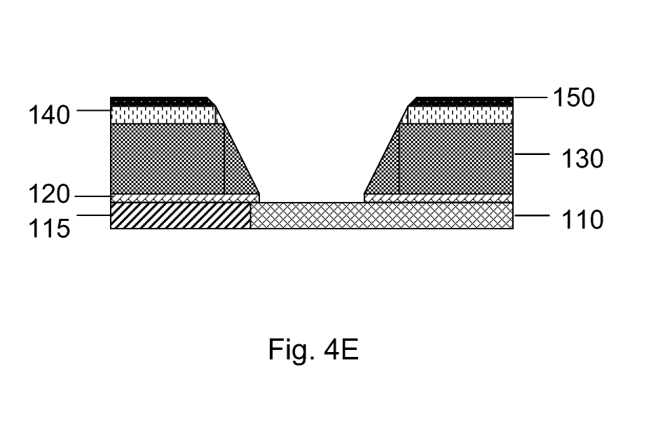

In one embodiment of the present disclosure, the etching process forms the trench down to the dielectric capping layer 120, as shown in FIGS. 4A-4D. This is called a partial etch. The dielectric capping layer 120 is left in this embodiment of the present disclosure as a barrier for the metallic device layer to protect against the wet etching process, that is, application of the chemical composition of the present disclosure. FIG. 4A shows the microelectronic device after a partial etch with residual etch residue 170. FIG. 4B shows the microelectronic device after a partial etch without the residual etch residue for clarity. Likewise, the residue is removed from FIGS. 4C-4E for clarity.

FIG. 4C shows the microelectronic device after a full wet etch process, that is, after application of the chemical composition of the present disclosure removing the entire metal hard mask layer 150. The chemical composition is applied to the microelectronic device at a temperature in the range of about 25° C. to about 80° C. Preferably, the chemical composition is applied at about 60° C. For total removal, the chemical composition is applied to the microelectronic device for about 1 minute to about 5 minutes.

It has been observed that there is a pattern density relationship to the wet removal of metal hard masks such as titanium nitride (TiN). This is not surprising based both on the incoming variation induced by prior reactive ion etch operations as well as possible chemical kinetic relationships. It is noted that in dense areas of the microelectronic device, an application of the chemical composition of the present disclosure for about 2 minutes is sufficient to achieve total removal of a titanium nitride (TiN) metal hard mask with a deposited thickness of about 300 A to about 400 A. Whereas, in blanket areas of the microelectronic device, the chemical composition is applied for about 4 minutes to achieve total removal. Total removal would remove all layers above the dielectric hard mask or inter-level dielectric layer if no dielectric hard mask layer is present.

A partial wet etch process can be performed as opposed to a total wet etch process as shown in FIG. 4D. A partial wet etch would clean and taper at least a part of the microelectronic device for future metallization of the device, which would help the aspect ratio of the device and as such improve metallization. In FIG. 4D, a portion of the metal hard mask layer 150 is removed after the partial wet etch process exposing a portion of dielectric hard mask layer 140. This helps to mitigate any potential damage to the metallic device layer 110. In order to perform a partial etch, the chemical composition is applied for about 1 minute to about 2 minutes at about 60° C. The wet etch, whether total or partial, is followed by an etching process to open the dielectric capping layer 120 and perform any additional tapering/hard mask chamfering necessary as shown in FIG. 4E. A cleaning process may also be performed after the etching process to remove any additional residues from the etching process.

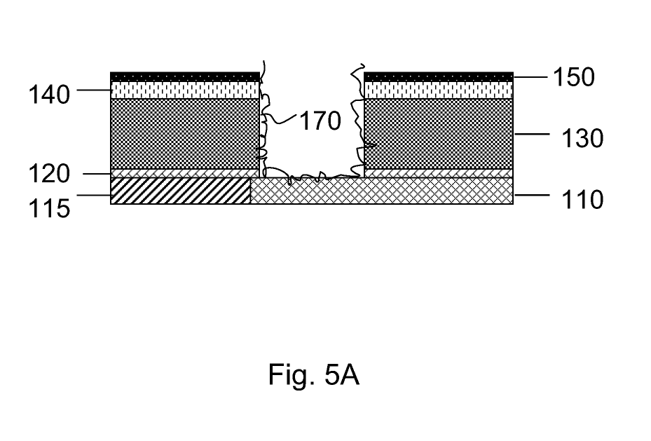

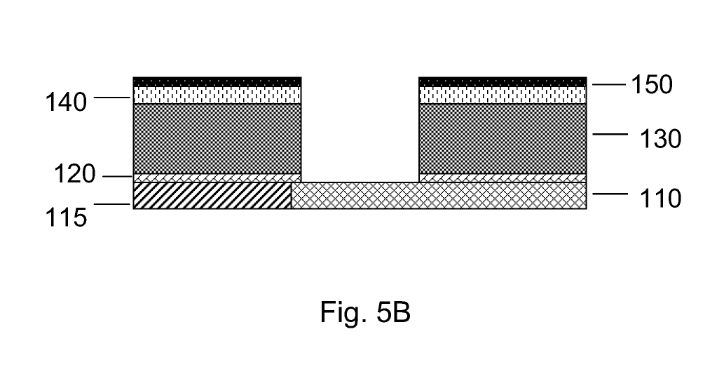

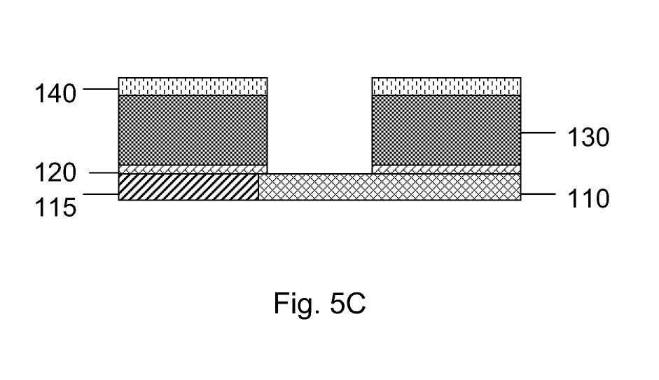

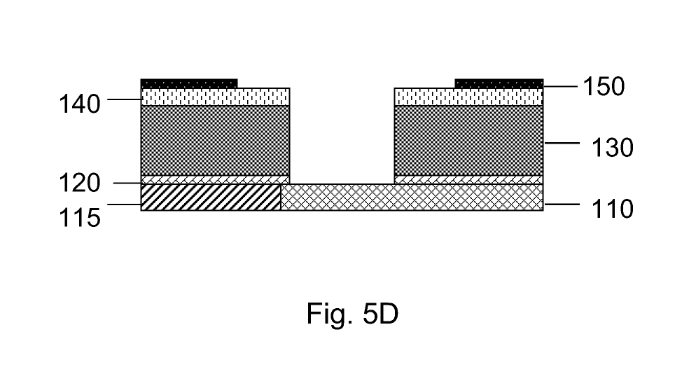

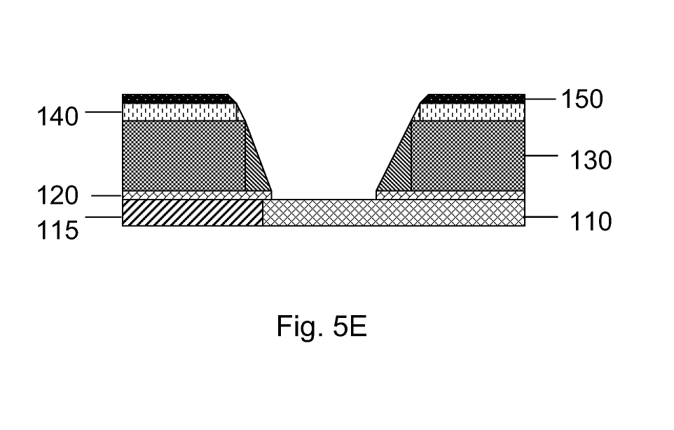

FIGS. 5A-5E show another embodiment of the present disclosure where the trench etching process forms the trench down to the metallic device layer 110. FIG. 5A shows the microelectronic device after a full etch with residual etch residue 170. FIG. 5B shows the microelectronic device after a full etch without the residual etch residue for clarity. Likewise, the residue is removed from FIGS. 5C-5E for clarity.

FIG. 5C shows the microelectronic device after a full wet etch process, that is, after application of the chemical composition of the present disclosure removing the entire metal hard mask layer 150. The chemical composition is applied to the microelectronic device at a temperature in the range of about 25° C. to about 80° C. Preferably, the chemical composition is applied at about 60° C. For total removal, the chemical composition is applied to the microelectronic device for about 1 minute to about 5 minutes. Total removal would remove the entire metal hard mask layer above the dielectric hard mask or inter-level dielectric layer if no dielectric hard mask layer is present.

It has been observed that there is a pattern density relationship to the wet removal of metal hard masks such as titanium nitride (TiN). This is not surprising based both on the incoming variation induced by prior reactive ion etch operations as well as possible chemical kinetic relationships. It is noted that in dense areas of the microelectronic device, an application of the chemical composition of the present disclosure for about 2 minutes is sufficient to achieve total removal of a titanium nitride (TiN) metal hard mask with a deposited thickness of about 300 A to about 400 A. Whereas, in blanket areas of the microelectronic device, the chemical composition is applied for about 4 minutes to achieve total removal. Total removal would remove all layers above the dielectric hard mask or inter-level dielectric layer if no dielectric hard mask layer is present. Partial removal would leave some metal hard mask structures, but modify the structures by a partial removal of the structures while preserving all layers below the dielectric hard mask such as the dielectric hard mask or inter-level dielectric layers if no dielectric hard mask layer is present.

A partial wet etch process can be performed as opposed to a total wet etch process as shown in FIG. 5D. A partial wet etch would clean and taper the microelectronic device, which would help the aspect ratio of the device. In FIG. 5D, a portion of the metal hard mask layer 150 is removed after the partial wet etch process exposing a portion of dielectric hard mask layer 140. This helps to mitigate any potential damage to the metallic device layer 110. In order to perform a partial etch the chemical composition is applied for about 1 minute to about 2 minutes at about 60° C. The partial wet etch may be followed by an etching process to perform any additional tapering/hard mask chamfering necessary as shown in FIG. 5E. A cleaning process may also be performed after the etching process to remove any additional residues from the etching process.

The chemical composition and its accompanying methods can be used for 64 nm pitch copper single and dual damascene interconnects using pitch split double patterning scheme to enable sub 80 nm pitch patterning, for example. After the trench pattern is formed, the trenches are to be filled with metal. The metallization process has become a challenge for recent technology generations with narrow width trenches patterned in low-k dielectric material with hard masks on top of the dielectric film. The trenches often have a high aspect ratio with undercut under the hard mask. To prevent metal fill defects, the metal hard mask can be removed using the chemical composition of the present disclosure using one of the methods described herein. This will significantly improve the metal fill process.

Trapezoidal structures in FIGS. 4E and 5E are exaggerated to illustrate possible chamfering of a structure by selective design, not by the lack of degrees of freedom to time a desired sidewall angle. A sidewall angle approximating 90 degrees to the copper plane may be constructed using the present disclosure. However, the present disclosure enables the construction of a trapezoidal cross-section, if such a structure is desired. A main difference is that this construction of a trapezoidal cross-section is by conscious design, rather than by an uncontrolled process side effect.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The working solution of the present disclosure eliminates or reduces copper attack observed when prior art solutions for titanium nitride removal, as well as in comparison to competing alternatives offered for metal hard mask removal. Further, the chemistry of the working solution increases the pH range of the etch solution that is compatible with processing on copper surfaces. In the course of the research leading to the present disclosure, it has been found that when the amount of the metal protectant is at least one order of magnitude greater than in prior art compositions, such as in our the present disclosure: that the pH range of the working solution can be lower, and more neutral, than the pH range of the solutions for etching titanium nitride as known in the art. Thus, due to the high concentration of the metal protectant, we may employ a pH range more suitable to organosilicate glass (OSG), silicon oxide, or other dielectric materials which are known to increase in etch behavior with the increase in pH of a basic solution.

In addition, the working solution of the present disclosure is compatible with both copper metallurgy and cobalt metallurgy, i.e., can be used without etching or pitting surfaces of copper, copper alloys, cobalt, or cobalt alloys.

Processes employing the working solution of the present disclosure can be performed in a wider process window compared with prior art solutions for etching titanium nitride because copper surfaces or cobalt surfaces are less susceptible to etch in the working solution of the present disclosure. Thus, the working solution of the present disclosure can be employed to remove metallic hard mask materials in a temperature range from 20° C. to 75° C., while prior art solutions require use in a narrow temperature range around 65° C., e.g., from 60° C. to 70° C. Further, if the reactivity of the working solution of the present disclosure can be enhanced by other means, for example, by sonication, the temperature of the etch process employing the working solution of the present disclosure can be decreased below 50° C., e.g., to a range between 20° C. and 50° C.

According to another embodiment of the present disclosure, a two-step etch process can be employed instead of a single etch step for removal of a hard mask layer. Specifically, a concentrated aqueous solution including a metal protectant and not including an oxidant can be applied to a patterned structure such as a structure of FIG. 4A, 4B, 4D, 4E, 5A, 5B, 5D, or 5E in a first step. The concentrated aqueous solution applied in the first step can be any of the stock solutions described above, or any diluted solution derived therefrom by adding water or a polar liquid without adding any oxidant. If a diluted solution is employed, the concentration of the metal protectant in the diluted solution can be greater than 1,000 p.p.m. The diluted solution may, or may not, include a pH stabilizer. If the metal protectant and the pH stabilizer are simultaneously employed, the pH of the diluted solution can be selected to minimize etching or damaging of dielectric material in the inter-level dielectric. For example, the pH of the diluted solution. The metal protectant in the stock solution, or in the diluted solution, covers metallic surfaces and forms a protective coating.

In the second step of the two-step etch process, a working solution of the present disclosure or any other etchant known to etch titanium nitride material can be employed. The working solution of the present disclosure or another etchants includes an oxidizing agent such as hydrogen peroxide.

All methods of the present disclosure can be employed with, or without, a dielectric capping layer. For example, the methods of the present disclosure can be employed with a dielectric capping layer 120 at a bottom of a cavity as lustrated in FIGS. 4A-4E, or can be employed without any dielectric capping layer at a bottom of a cavity as illustrated in FIGS. 5A-5E.

In one embodiment, a method of removing a metal hard mask and etching residues from a microelectronic device includes steps of etching a trench in an interconnect structure by a reactive ion etching process (RIE) through a stack including at least a metal hard mask layer, a dielectric hard mask layer, and an inter-layer dielectric as described above. A first wet chemical composition can be applied to the interconnect structure. The first wet chemical composition includes at least one metal protectant in a first aqueous solution at a concentration in a range from 1,000 p.p.m. to 400,000 p.p.m. in weight percentage. The first wet chemical composition can be any of the stock solution described above, or can be any of the working solution described above. In another embodiment, the first wet chemical composition can be derived from the stock solution by diluting the stock solution without adding hydrogen peroxide or any other oxidizing agent, i.e., only by adding water or a polar solvent in which water is the predominant solvent. The dilution can be performed in any degree provided that the concentration of the at least one metal protectant is at least 1,000 p.p.m. in weight percentage.

Subsequently, a second wet chemical composition for removing the metal hard mask layer selective to the dielectric hard mask layer and the inter-layer dielectric is applied to the interconnect structure. The chemical composition includes at least an oxidizing agent selected from peroxides and oxidants which do not leave a residue and do not adversely attack copper, a pH stabilizer selected from quaternary ammonium salts and quaternary ammonium alkali, and a second aqueous solution, wherein the composition has a pH in the range of about 7 to about 14.

In one embodiment, the trench is etched selective to a dielectric capping layer that underlies the inter-layer dielectric, and the method further comprises etching through a portion of the dielectric capping layer underneath the trench to physically expose a metallic surface of a metallic device layer. In another embodiment, the trench is etched selective to a metallic material of a metallic device layer underlying the inter-layer dielectric.

The pH stabilizer may be present in the second wet chemical composition at a concentration having a weight percentage in a range from 0.14% to 35%. The second wet chemical composition can be any of the working solutions described above, or any of the prior art etch solutions for removing a metal hard mask layer.

The corresponding structures, materials, acts, and equivalents of all means or step plus function elements in the claims below are intended to include any structure, material, or act for performing the function in combination with other claimed elements as specifically claimed. It is well known that different deposition conditions may result in metal films such as titanium nitride (TiN) hard mask films with different properties. Accordingly, the chemical ratios and/or contact times may be adjusted to produce similar results with varying titanium nitride (TiN) or other metal hard mask films. Thus, the description of the present disclosure has been presented for purposes of illustration and description, but is not intended to be exhaustive or limited to the disclosure in the form disclosed.

The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A chemical composition for removing a metal hard mask and etching residues from a microelectronic device comprising:
at least one metal protectant at a concentration in a range from 1,000 p.p.m. to 50,000 p.p.m. in weight percentage;
an oxidizing agent selected from peroxides and oxidants which do not leave a residue and do not adversely attack copper;
a pH stabilizer including at least one quaternary ammonium salt or at least one quaternary ammonium alkali; and
an aqueous solution.

2. The chemical composition of claim 1, further comprising a sequestering agent selected from amines and amino acids.

3. The chemical composition of claim 2, wherein the sequestering agent is at least one of 1,2-cyclohexanediamine-N,N,N′,N′-tetraacetic acid (CDTA), ethyenediaminetetraacetic acid (EDTA) and diethylenetriaminopentaacetic acid (DTPA).

4. The chemical composition of claim 1, wherein the metal protectant is at least one of benzotriazole, 1,2,3 triazole, 1,3,4 triazole, 1,2,4 triazole, imidazole, methyl-thiol-triazole, thiol-triazole, and triazole acid.

5. The chemical composition of claim 1, wherein the oxidizing agent comprises at least one of hydrogen peroxide (H₂O₂) and benzoyl peroxide (C₁₂H₁₀O₄).

6. The chemical composition of claim 1, wherein the pH stabilizer is tetraethylammonium hydroxide (TEAH).

7. The chemical composition of claim 1, wherein the aqueous solution comprises de-ionized water.

8. The chemical composition of claim 1, wherein the composition comprises hydrogen peroxide (H₂O₂), benzotriazole, tetraethylammonium hydroxide, and de-ionized water, and wherein the composition has a pH in the range of about 7 to about 9.

9. A chemical composition for a stock solution for generating an etch solution for removal of a metallic material, the chemical composition comprising:
at least one metal protectant at a concentration in a range from 10,000 p.p.m. to 400,000 p.p.m. in weight percentage;
a pH stabilizer including at least one quaternary ammonium salt or at least one quaternary ammonium alkali; and
an aqueous solution.

10. The chemical composition of claim 1, further comprising a sequestering agent selected from amines and amino acids.

11. The chemical composition of claim 10, wherein the sequestering agent is at least one of 1,2-cyclohexanediamine-N,N,N′,N′-tetraacetic acid (CDTA), ethyenediaminetetraacetic acid (EDTA) and diethylenetriaminopentaacetic acid (DTPA).

12. The chemical composition of claim 1, wherein the metal protectant is at least one of benzotriazole, 1,2,3 triazole, 1,3,4 triazole, 1,2,4 triazole, imidazole, methyl-thiol-triazole, thiol-triazole, and triazole acid.

13. The chemical composition of claim 1, wherein the pH stabilizer is tetraethylammonium hydroxide (TEAH).

14. A method of removing a metal hard mask and etching residues from a microelectronic device comprising steps of:
etching a trench in an interconnect structure by a reactive ion etching process (RIE) through a stack including at least a metal hard mask layer and an inter-layer dielectric; and
applying a wet chemical composition for removing the metal hard mask layer selective to the inter-layer dielectric, the chemical composition comprising at least one metal protectant at a concentration in a range from 1,000 p.p.m. to 50,000 p.p.m. in weight percentage, an oxidizing agent selected from peroxides and oxidants which do not leave a residue and do not adversely attack copper, a pH stabilizer including at least one quaternary ammonium salt or at least one quaternary ammonium alkali, and an aqueous solution, wherein the composition has a pH in the range of about 7 to about 14.

15. The method of claim 14, wherein the trench is etched selective to a dielectric capping layer that underlies the inter-layer dielectric, and the method further comprises etching through a portion of the dielectric capping layer underneath the trench to physically expose a metallic surface of a metallic device layer.

16. The method of claim 14, wherein the trench is etched selective to a metallic material of a metallic device layer underlying the inter-layer dielectric.

17. The method of claim 14, wherein a dielectric hard mask layer is provided between the metal hard mask layer and the inter-layer dielectric, and the wet chemical composition removes a metal hard mask layer on the interconnect structure selective to the dielectric hard mask layer by applying the composition in a range from about 1 minute to about 5 minutes at a temperature in the range of about 25° C. to about 80° C.

18. The method of claim 14, wherein a dielectric hard mask layer is provided between the metal hard mask layer and the inter-layer dielectric, and the wet chemical composition partially removes layers on the interconnect structure selective to the dielectric hard mask layer by applying the composition in a range from about 1 minute to about 2 minutes at a temperature of about 60° C.

19. A method of removing a metal hard mask and etching residues from a microelectronic device comprising steps of:
etching a trench in an interconnect structure by a reactive ion etching process (RIE) through a stack including at least a metal hard mask layer and an inter-layer dielectric;
applying a first wet chemical composition including at least one metal protectant in a first aqueous solution at a concentration in a range from 1,000 p.p.m. to 400,000 p.p.m. in weight percentage; and
applying a second wet chemical composition for removing the metal hard mask layer selective to the inter-layer dielectric, the chemical composition comprising at least an oxidizing agent selected from peroxides and oxidants which do not leave a residue and do not adversely attack copper, a pH stabilizer including at least one quaternary ammonium salt or at least one quaternary ammonium alkali, and a second aqueous solution, wherein the composition has a pH in the range of about 7 to about 14.

20. The method of claim 19, wherein the trench is etched selective to a dielectric capping layer that underlies the inter-layer dielectric, and the method further comprises etching through a portion of the dielectric capping layer underneath the trench to physically expose a metallic surface of a metallic device layer.

21. The method of claim 19, wherein the trench is etched selective to a metallic material of a metallic device layer underlying the inter-layer dielectric.

22. The method of claim 19, wherein the pH stabilizer is present at a concentration having a weight percentage in a range from 0.14% to 35%.

23. A method of forming a chemical solution, the method comprising dissolving at least one metal protectant in an aqueous solution including a pH stabilizer at a concentration greater than a solubility limit of the at least one metal protectant in deionized water to form a stock solution.

24. The method of claim 23, wherein the at least one metal protectant is present at a concentration in a range from 10,000 p.p.m. to 400,000 p.p.m. in weight percentage, and the pH stabilizer is selected from quaternary ammonium salts and quaternary ammonium alkali.

25. The method of claim 23, further comprising diluting the stock solution with water and an oxidant, wherein an etchant for removing a metallic material is formed.
